(19) United States
(12) Patent Application Publication
(10) Pub. No.: US 2009/0230488 A1
(43) Pub. Date: Sep. 17, 2009

(54) Low dark current image sensor

(75) Inventor: Takashi Ando, Hartsdale, NY (US)

Correspondence Address: RADER FISHMAN & GRAUER PLLC, LION BUILDING, 1233 20TH STREET N.W., SUITE 501, WASHINGTON, DC, 20036, US

(73) Assignees: Sony Corporation, Tokyo (JP); Sony Electronics, Inc., Park Ridge, NJ (US)

(21) Appl. No.: 12/076,299

(22) Filed: Mar. 17, 2008

(51) Int. Cl. H01L 31/0232; H01L 31/18

(52) U.S. Cl. 257/432; 438/57; 257/E31.127

(57) ABSTRACT

Imaging sensors (CMOS image sensor, CCD) with low dark current. The disclosed embodiments employ a stacked structure directly on the sensing area. The stack structure an SiO₂ layer and with an HfO₂ which is doped with Al, Ta, Be, Co, or Ge at the vicinity of the interface. The invention is not limited to an HfO₂layer, but may also employ Hf-silicate, ZrO₂, or Zr-silicate. These stacks exhibit a larger amount of fixed charges than the single film of HfO₂. This results in a hole accumulation diode which has a lower dark current. In addition, the doping of the HfO₂ layer makes the stacked structure thermally stable up to 1000 C, which widens the options of manufacturing process.

### CROSS REFERENCE TO RELATED APPLICATIONS

This application is related to commonly assigned U.S. application Ser. No. ______, filed on ______ by Takashi Ando, and entitled “Low Dark Current Image Sensors by Substrate Engineering” (Attorney Docket No. SOA-0418).

### BACKGROUND OF THE INVENTION

1. Field of the Invention

This invention relates generally to image sensors and the manufacture of image sensors having low dark current and more particularly to CMOS and CCD imaging sensors having low dark current characteristics.

2. Description of the Related Art

Modern digital cameras employ either CCD (charge coupled device) or CMOS (complementary metal oxide semiconductor) image capture sensors. CCD and CMOS technologies offer alternative methods for capturing images onto digital media.

The architecture of the CCD is largely devoted to light capture and processing is done mostly off-chip. By contrast, CMOS sensor architecture is more complex than CCD architecture. Within CMOS imaging sensors, each pixel cell typically includes a circuit that transforms photons from a photoactive-diode to a digital charge. With each pixel doing its own conversion, the chip can be built to require less off-chip circuitry for basic operation.

While CCD and CMOS architecture differs, both CCD (charge-coupled device) and CMOS (complimentary metal-oxide semiconductor) image sensors convert light into electrons using a plurality of photoactive-diodes, also known as photo-diodes, cells, or photo-sites.

The photo-diodes are generally arranged in a 2-D lattice. Each photo-diode in the lattice transforms light into an electron charge. Within the lattice, each photo-diode corresponds to at least one pixel in the captured image. Photo-diodes exhibit a photoelectric effect, characterized by the ability of certain materials to release an electron when impacted by protons, thereby creating a charge. The more photons impact a given photo-diode, the more charge builds up. Each diode is bordered by a nonconductive boundary, which forces the charge to build while the diode is exposed to light from a camera aperture. In essence, each of the photo-diodes acts as a bucket, tracking the number of incoming photons making contact with the photo-diode. The accumulated charge in each diode is measured and recorded as a corresponding brightness value.

FIG. 1 illustrates a cross-sectional view of a conventional CMOS image sensor 1. This CMOS image sensor 1 exhibits high dark currents and defects caused by ion-implantation. CMOS image sensor 1 includes anti-reflection layer 5, a hole accumulation diode 20, and sensing area 10. The hole accumulation diode 20 includes a doped layer 15 having a p-type implantation species 15, such as boron. The hole accumulation diode 20 is highly doped with p-type impurities in-situ formed by an epitaxial growth process. Anti-reflection layer 5 serves to prevent incoming photons from reflecting off the surface of the photo-diode, and thereby failing to register a charge. The anti-reflection layer 5 may be comprised of silicon nitride (SiN).

FIG. 2 is a schematic diagram illustrating an energy bands of the stacked structure of conventional CMOS image sensor 1, described in FIG. 1. The horizontal axis correspond to increasing depth of the CMOS image sensor 1, beginning at anti-reflection layer 5, p-type implantation 15 area, and sensing area 10. The vertical axis represents the energy band. Dashed line 50 represents the interface between the sensing area 10 and p-type implant species 15. Energy bands 55 represent the range of band gap 65, having a mid-gap 60. A hole accumulation layer is formed at the surface of the sensing area 10 due to p-type implant species in doped layer 15. As a result, the energy bands 55 bend upward as they approach the interface between the anti-reflection layer 5 and the sensing area 10, which may lower dark current. On the other hand, defects are introduced at the surface of the sensing area by the implantation process (shown by X'es in FIG. 2). These defects are the origins of the dark current.

To reduce the dark current in the photo-diode, it may be beneficial to reduce the number of electrons at interface 50, thereby reducing the number of electrons entering sensing area 10. The conventional CMOS image sensor 1 attempts to do this by introducing the doped layer 15, however, electrons can pass through doped layer 15.

The CCD and CMOS are manufactured via a wafer fabrication process by which different electrical components and structures are formed on the silicon wafers. Fabrication includes a plurality of stages, include deposition, photolithography, etching, ion implantation, and annealing. Conventional photo-diodes have p-type doping (usually Boron) and are grown upon the substrate material.

During the deposition stage uniform coatings of thin films are applied to the wafers. Materials such as silicon dioxide, silicon nitride and polycrystalline silicon can be deposited onto the wafers using a variety of techniques, such as evaporation, chemical vapor deposition and sputtering. In particular, photo-diodes can be generated by forming epitaxial silicon layers using a process known as chemical vapor deposition.

Photolithography and etching are the processes by which structures are created on the wafers. Photolithography commonly employs UV sensitive chemicals to form masks, which acts as stencils. Etching techniques are used to remove materials that decompose during the photolithography process.

The doping process introduces ions into the fabricated surfaces, thereby adding impurities and changing the electrical properties of the material into which the ions are implanted. During the doping process, the wafers are bombarded with ions which are thereby implanted into the silicon. The number of ions implanted via the bombardment process is controlled in order to produce surface layers with specific electrical properties.

Alternatively, an epitaxial layer can be doped during deposition by adding impurities to the source gas, such as arsine, phosphine or diborane. The concentration of impurity in the gas phase determines its concentration in the deposited film. As in CVD, impurities change the deposition rate.

In the annealing process, wafers are heated for a specific amount of time in a conditioned atmosphere (inert, oxidizing, reducing). This process serves to remove impurities (such as oxygen) from the surface layers and cause implanted ions to diffuse further into the silicon (called “autodoping”).

A common problem among imaging sensors is that even in the absence of light, some electrons will accumulate in the photo-diodes. This phenomenon is called “dark current.” Dark current within image sensors degrades the performance of the produced image. These dark currents are not generated by incoming photons, but are randomly generated by thermal excitation, current leaks within the imaging device, or from various other possible sources. When charges buildup in the photo-diode, the dark current is indistinguishable from charge resulting from the photoactive effect. This causes the dark current to effectively brighten areas of the captured image, and unevenly reduces contrast between dark and lighter areas of the image. Because dark current electrons are random with respect to each imaging device, their effects on each photo-diode is unpredictable, and thereby produces noise in the resulting image which is difficult to remove. Therefore, in order to provide clearer contrast and reliable color dark currents should be minimized.

The prior art attempts to address this problem by forming a hole accumulation diode using an ion-implantation. However, this method requires high temperature processes, and therefore narrows the options for manufacturing processes. In addition the implantation process itself causes defects in the sensing area of the imaging device.

### SUMMARY OF THE INVENTION

The present invention is directed to an imaging sensors (CMOS image sensor, CCD) with low dark current. The disclosed embodiments employ a stacked structure directly on the sensing area. The stack structure an SiO₂ layer and with an HfO₂ which is doped with Al, Ta, Be, Co, or Ge at the vicinity of the interface. The invention is not limited to an HfO₂ layer, but may also employ Hf-silicate, ZrO₂, or Zr-silicate. These stacks exhibit a larger amount of fixed charges than the single film of HfO₂. This results in a hole accumulation diode which has a lower dark current. In addition, the doping of the HfO₂ layer makes the stacked structure thermally stable up to 1000 C, which widens the options of manufacturing process.

One embodiment may include an image sensor comprising a silicon substrate, a doped layer formed by p-type species implantation onto the silicon substrate, a first layer disposed on the doped layer, and a second layer disposed on the first layer. The first layer may be made of silicon, SiO₂, or SiN. The second layer may be a layer of HfO₂, Hf-silicate, ZrO₂, or Zr-silicate. The second layer may also be doped with Al, Ta, Be, Co, or Ge.

Another embodiment may include an image sensor comprising a silicon substrate, a doped layer formed by p-type species implantation onto the silicon substrate, a peripheral circuit adjacent to the silicon substrate and doped layer. The embodiment may also include a first layer disposed on the doped layer and peripheral circuit, and a second layer disposed on the first layer. The first layer may be made of silicon, SiO₂, or SiN. The second layer may be a layer of HfO₂, Hf-silicate, ZrO₂, or Zr-silicate. The second layer may also be doped with Al, Ta, Be, Co, or Ge. The embodiment may also include a light shield disposed a portion of the first layer and second layer, overlapping the peripheral circuit; Alternatively, the light shield may be disposed directly on the peripheral circuit. The imaging sensor may also include an anti-reflection layer and color filter disposed over the anti-reflection layer and overlapping the silicon substrate.

Yet another embodiment may be directed to a process for manufacturing an image sensor. The process includes producing a silicon substrate, implanting a p-type species along a surface of the silicon substrate to form a doped layer, growing a first layer disposed on the doped layer, comprising silicon, growing a second layer disposed on the first layer comprising at least one of HfO₂, Hf-silicate, ZrO₂, or Zr-silicate. The process may also comprise doping the third layer is doped with Al, Ta, Be, Co, or Ge.

The present invention can be embodied in various forms, including business processes, computer implemented methods, computer program products, computer systems and networks, user interfaces, application programming interfaces, and the like.

### BRIEF DESCRIPTION OF THE DRAWINGS

These and other more detailed and specific features of the present invention are more fully disclosed in the following specification, reference being had to the accompanying drawings, in which:

FIG. 1 is a schematic diagram illustrating a conventional CMOS image sensor.

FIG. 2 is a schematic diagram illustrating an energy bands of the stacked structure of a conventional CMOS image sensor

FIG. 3 is a schematic diagram illustrating an example embodiment of an image sensor in a accordance with the present invention.

FIG. 4 is a schematic diagram illustrating another example of an image sensor in a accordance with the present invention.

FIG. 5 is a schematic diagram illustrating energy bands of an example of an image sensor in accordance with the present invention.

FIGS. 6A-6D illustrate an example of a method for manufacturing a hole accumulation diode.

FIG. 7 is a schematic diagram illustrating an example of an image sensor employing a hole accumulation diode.

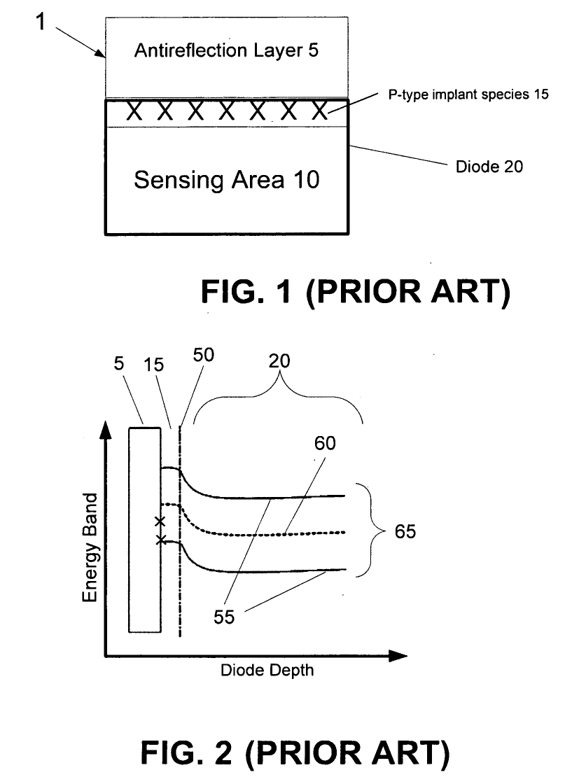

### DETAILED DESCRIPTION OF THE INVENTION

In the following description, for purposes of explanation, numerous details are set forth, such as flowcharts and system configurations, in order to provide an understanding of one or more embodiments of the present invention. However, it is and will be apparent to one skilled in the art that these specific details are not required in order to practice the present invention.

The present invention is directed to image sensors and the manufacture of image sensors having low dark current. The invention improves on pre-existing technologies by taking advantage of the narrower energy band gap of Ge and SiGe, as compared to imaging sensors employing conventional Si substrates.

The present invention relates to imaging sensors (e.g., CMOS image sensor and CCDs) exhibiting low dark current. The disclosed embodiments employ a stacked structure directly on the sensing area of photoactive-diode. The stack exhibits a larger quantity of fixed charges than conventional photo-diodes. This results in a hole accumulation diode having a lower dark current. In one embodiment, doping within the stack makes the stacked structure thermally stable up to 1000° C., which widens the options of manufacturing process.

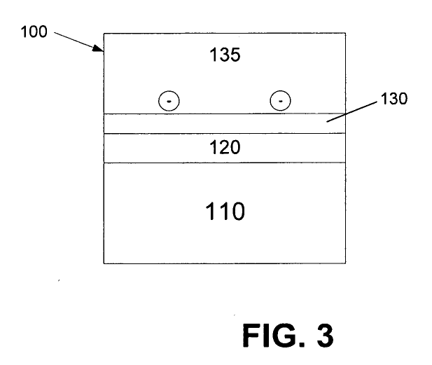

FIG. 3 illustrates an example embodiment of an image sensor in accordance with the present inventions. The image sensor include an anti-reflection layer and a hole accumulation diode, a type of photo-diode. The hole accumulation diode 110 includes a sensing area 120, a doped layer 125. The anti-reflection layer includes a first layer 130 and a second layer 135.

The doped layer 125 is comprised of a silicon layer doped with p-type impurities. This doped layer 125 may have a thickness of up to 10 nm and may be selectively implanted onto the silicone substrate of the sensing area 120 using any common methods known in the conventional art.

After the doped layer 125 is formed, the first layer 130 may be deposited on the doped layer 125 via surface oxidation, such as via ozone annealing or chemical treatment annealing. First layer 130 is made of pure silicon or SiO₂. The first layer 130 preferably has a thickness of up to 3 nm.

The second layer 135 may comprise HfO₂, Hf-silicate, ZrO₂, or Zr-silicate. This layer may have a thickness ranging from 10-100 nm. The thickness of the second layer 135 affects the sensitivity of the imaging device 100 with respect to different wavelengths of light. For example, if the second layer has a thickness is the a range of about 16 nm, the imaging device will have an affinity to blue light.

The first and second layer, 130 and 135 create an interface that exhibits a larger quantity of fixed charges than a film of HfO₂ alone. The use of a silicon layer for the first layer 130 reduces the defect density of the substrate by introducing a buffer between the doped layer 125 and third layer 135, resulting in lower dark currents.

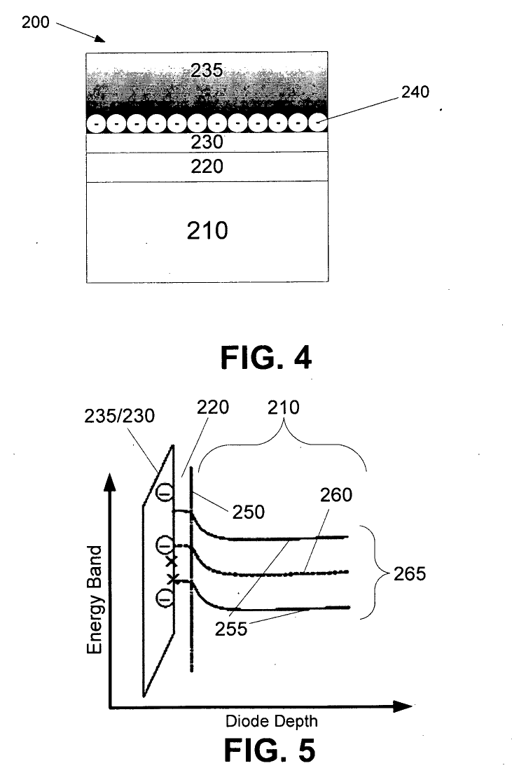

The image sensor 200 of FIG. 4 accommodates for the possibility that the image sensor 100 illustrated in FIG. 3 may not contain sufficient fixed charge at the interface of the first layer 130 and the second layer 135. Furthermore, the structure may be thermally unstable.

FIG. 4 illustrates the image sensor 200. Image sensor 200 includes a sensing area 220, a doped layer 225, a first layer 230 and a second layer 235.

The doped layer 225 is produced by implanting p-type impurities on a surface of sensing area 210. This doped layer 225 may have a thickness of up to 10 nm and may be selectively grown on the silicone substrate of the sensing area 210 using any common methods known in the conventional art.

After the doped layer 225 is formed, the first layer 230 may be deposited on the doped layer 225. The first layer 230 is preferably a silicon layer grown to a thicknesses of up to 3 nm via surface oxidation, such as an Ozone annealing process, or chemical treatment annealing. First layer 130 is made of pure silicon (Si), SiN, or SiO₂. The first layer 230 acts as a buffer, reducing the interface states between sensing area 210/doped layer 220 and the first and second layers, 230 and 235.

The second layer 235 may comprise HfO₂, Hf-silicate, ZrO₂, or Zr-silicate. The second layer 235 is also doped with p-type impurities, such as for example, Al, Ta, Be, Co, or Ge. This layer may have a thickness ranging from 10-100 nm. Similarly to second layer 135, the thickness of the second layer 135 affects the sensitivity of the imaging device 100 with respect to different wavelengths of light.

The introduction of the p-type impurities into the second layer 235 places a larger number of fixed charges in the second layer 235, which creates an interface that exhibits a larger quantity of fixed charges than the undoped layer second layer 135 illustrated in FIG. 3. The use of a Silicon in the second layer 230 reduces the defect density of the hole accumulation diode resulting in lower dark currents. Furthermore, the doped impurities in the second layer 235 also improve the thermal stability of the imaging sensor, making it tolerant to temperatures of up to 1000° C., as compared with the second layer 135 in FIG. 3.

FIG. 5 is a schematic illustrating an energy band diagram of the stacked structure of CMOS image sensor 200, described in FIG. 4. The horizontal axis correspond to increasing depth of the diode, passing an anti-reflection layer made of second layer 235 and first layer 230, as well as doped layer 220 and sensing area 210. Energy bands 255 represent the range for band gap 265, having a mid-gap 260. The energy bands 255 begin curving at interface 250 between sensing are 210 and doped layer 220.

A hole accumulation layer is formed at the surface of the sensing area 210 and doped layer 220 due to additional fixed charges introduced by the dopants in the second layer 235 (shown by minus signs in FIG. 5). As a result, the magnitude of the band bending near the interface between the anti-reflection layer and the sensing area becomes larger. Moreover, the amount of p-type implant species in the doped layer 225 can be reduced and the density of the interface defects becomes lower.

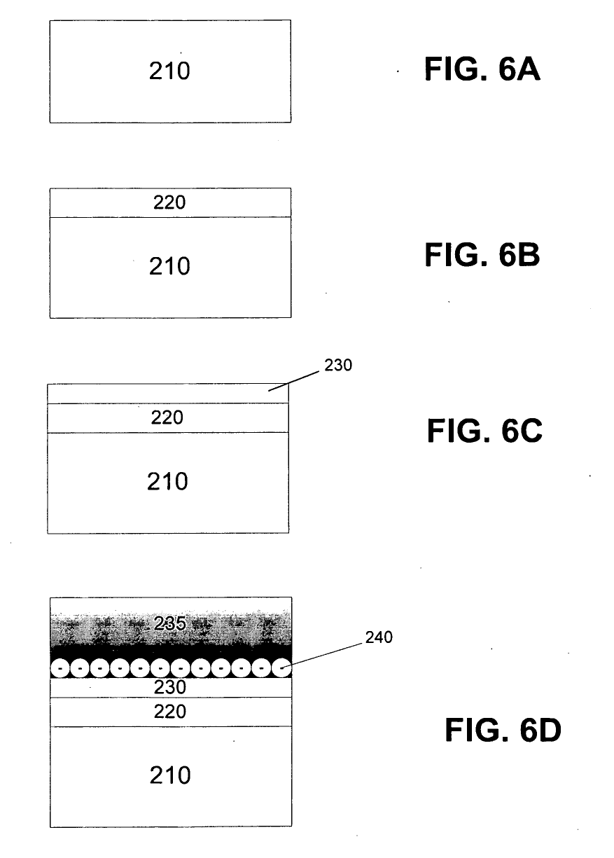

FIGS. 6A-6D illustrate a method for manufacturing a diode in accordance with the present invention.

FIG. 6A illustrates the silicon wafer substrate comprising the sensing area 210 before any growth of the first layer 225 or second layer 230.

FIG. 6B illustrates the doped layer 225 is formed over the sensing area 220 via implantation of p-type impurities (e.g. boron or BF₂.). Thereafter the imaging sensor passes through a furnace annealing process. The furnace annealing process is performed in an atmosphere of nitrogen (N₂), hydrogen (H₂), or a mixture of N₂ and H₂.

FIG. 6C illustrates the growth of the first layer 230. The first layer 230 is an undoped silicon layer grown via surface oxidation oxidation, such as an Ozone annealing process, or chemical treatment annealing., to a thickness ranging up to 3nm, in an in-situ manner. The first layer 230 may be comprised of Silicon, SiO, or SiN.

FIG. 6D illustrates the growth of the second layer 235, after FIG. 6C, to form the second example embodiment shown in FIG. 4. As set forth above, this layer may comprise HfO₂, Hf-silicate, ZrO₂, or Zr-silicate. The second layer 235 may be doped with p-type impurities, such as for example, Al, Ta, Be, Co, or Ge, and grown to a thickness between 10-100 nm, in an in-situ manner.

To manufacture a diode in accordance with the first example embodiment shown in FIG. 3, the same process is performed, except the third layer 235 is replaced with an undoped layer of HfO₂, Hf-silicate, ZrO₂, or Zr-silicate.

While these layers are being formed, peripheral circuit areas may be covered by hard masks like SiO₂ or SiN to prevent growth of the first and/or second layer material over these peripheral circuits. After the steps described here, standard manufacturing processes of CMOS sensors or CCDs can be applied.

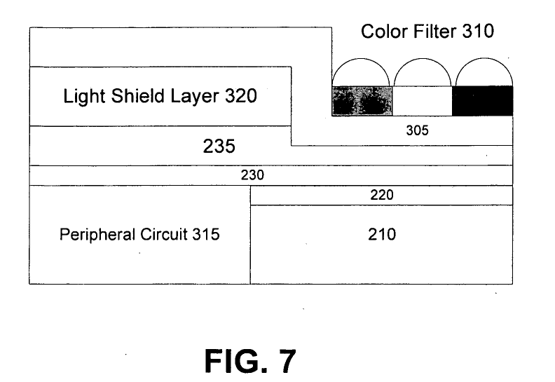

FIG. 7 illustrates another schematic diagram of an image sensor in accordance with the present invention. The image sensor includes anti-reflection layer 305, color filters 310, light shield layer 320, and peripheral circuit 315, and a photo diode. The photo-diode is represented by sensing area 210, doped layer 225, first layer 230, and second layer 235. Peripheral circuit 315 is protected from light exposure by light shield 320, to prevent fluctuations in performance due to the excitation of electrons in the peripheral circuit. Peripheral circuit 315 is built during the same process or in conjunction with the sensing area 210 and the doped layer 225.. This allows the second and third layers, 230 and 235, to form over the peripheral circuit 315. While in this embodiment the first layer 230 and second layer 235 extend over the peripheral circuit 315, the peripheral circuit 315 may be protected from growth of first and second layer 230 and 235, using an additional etching process.

During operation, light passes through color filters 310, anti-reflection layer 305, second layer 235, and first layer 230, doped layer 225 and into sensing area 210. As a result, the photo-diode forms a charge corresponding to the photons impacting the diode surface. This charge can be read, using the peripheral circuit 315, to determine the number of photons impacting the diode. The peripheral circuit 315 may contain a CPU, DSP, storage media, or any other related functionality for reading and transferring the charge produced in the diode to an outside circuit for processing.

While embodiments herein are discussed primarily with respect to three embodiments of an imaging sensor, the present invention is not limited thereto. For example, different materials or combinations thereof may be employed to form the various diode layers or as doping agents to the various diode layer, thereby allowing multiple variations is the techniques and methods for formation of the diodes.

Although embodiments of the invention are discussed primarily with respect to apparatuses and method manufacturing the imaging sensor and photo-diode, other uses and features are possible. Various embodiments discussed herein are merely illustrative, and not restrictive, of the invention. For example, different material, growth processes and doping agents can change the thermal stability and dark current exhibited by the imaging sensor.

Various embodiments of the present invention may provide important capabilities and features for electronic devices employing CMOS or CCD imaging sensors. Such capabilities and features include: greater freedom in manufacturing due to the variant thermal stabilities offered and reducing in dark current, leading to a reduction in the need to filter and otherwise compensate for noise within images. For example, the need to account for dark current via software solutions can be reduced or eliminated.

Those skilled in the art may construct imaging sensors by alter the chemistry of the imaging sensor to change the thermal or dark current exhibited in the disclosed image sensor without undue experimentation. Conventional systems for inducing changes in material chemistry may be adapted for use with embodiments of the present invention without departing from the scope thereof.

In the description herein, numerous specific details are provided, such as examples of components and/or methods, to provide a thorough understanding of embodiments of the present invention. One skilled in the relevant art will recognize, however, that an embodiment of the invention can be practiced without one or more of the specific details, or with other apparatus, systems, assemblies, methods, components, materials, parts, and/or the like. In other instances, well-known structures, materials, or operations are not specifically shown or described in detail to avoid obscuring aspects of embodiments of the present invention.

Thus embodiments of the present invention produce and provide systems and methods for low dark current imaging sensors. Although the present invention has been described in considerable detail with reference to certain embodiments thereof, the invention may be variously embodied without departing from the spirit or scope of the invention. Therefore, the following claims should not be limited to the description of the embodiments contained herein in any way.

1. An image sensor comprising:
a silicon substrate;
a doped layer formed by p-type species implantation on the silicon substrate;
a first layer disposed on the doped layer, comprising silicon;
a second layer disposed on the first layer comprising at least one of HfO₂, Hf-silicate, ZrO₂, or Zr-silicate.

2. The imaging sensor of claim 1, wherein doped layer has a thickness between about 1-10 nm.

3. The imaging sensor of claim 1, wherein the first layer has a thickness between about 1-3 nm.

4. The imaging sensor of claim 1, wherein at least one of the first layer is grown using surface oxidation or chemical treatment.

5. The imaging sensor or claim 1, wherein the second layer is doped with Al, Ta, Be, Co, or Ge.

6. An image sensor comprising:
a silicon substrate;
a doped layer formed by p-type species implantation on the silicon substrate;
a peripheral circuit adjacent to the silicon substrate and doped layer;
a first layer disposed on the doped layer and peripheral circuit, comprising silicon;
a second layer disposed on the first layer comprising at least one of HfO₂, Hf-silicate, ZrO₂, or Zr-silicate.
a light shield disposed a portion of the first layer and second layer, overlapping the peripheral circuit;
an anti-reflection layer disposed over the second layer and light shield.

7. The imaging sensor of claim 6, further comprising a color filter disposed over the anti-reflection layer and overlapping the silicon substrate.

8. The imaging sensor of claim 6, wherein the doped layer has a thickness between about 1-10 nm.

9. The imaging sensor of claim 6, wherein the first layer has a thickness between about 1-3 nm.

10. The imaging sensor or claim 6, wherein the second layer is doped with Al, Ta, Be, Co, or Ge.

11. A process for manufacturing an image sensor comprising:
producing a silicon substrate;
implanting a p-type species along a surface of the silicon substrate to form a doped layer;
growing a first layer disposed on the doped layer, comprising silicon;
growing a second layer disposed on the first layer comprising at least one of HfO₂, Hf-silicate, ZrO₂, or Zr-silicate.

12. The process of claim 11, wherein the doped layer has a thickness between about 1-10 nm.

13. The process of claim 11, wherein growing the first layer employs maximum temperatures over 500° C., then the second layer is doped with Al, Ta, Be, Co, or Ge.

14. The process of claim 11, wherein the first layer has a thickness of up to 3 nm.

15. The process of claim 11, further comprising doping the third layer is doped with Al, Ta, Be, Co, or Ge.
